(19) United States
(12) Patent Application Publication
(10) Pub. No.: US 2012/0052323 A1
(43) Pub. Date: Mar. 1, 2012

(54) PROCESS FOR SURFACE TREATING ALUMINUM OR ALUMINUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); XIAO-QING XIONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/170,925

(22) Filed: Jun. 28, 2011

(30) Foreign Application Priority Data
Aug. 26, 2010 (CN) 201010263699.2

(51) Int. Cl. B32B 15/01; C23C 14/35; C23C 14/06

(52) U.S. Cl. 428/651; 204/192.15; 428/650

(57) ABSTRACT

A method for surface treating aluminum or aluminum alloy, the method comprising the following steps of: providing a substrate made of aluminum or aluminum alloy; forming a TiON coating on the substrate by magnetron sputtering, using aluminum as a target, and nitrogen and oxygen as reactive gases; and forming a CrON coating on the TiON coating by magnetron sputtering, using chromium as a target, and nitrogen and oxygen as reactive gases.

### CROSS-REFERENCE TO RELATED APPLICATIONS

This application is related to co-pending U.S. patent application (Attorney Docket No. US35132, US36068, each entitled “PROCESS FOR SURFACE TREATING ALUMINUM OR ALUMINUM ALLOY AND ARTICLE MADE WITH SAME”, by Chang et al. These applications have the same assignee as the present application. The above-identified applications are incorporated herein by reference.km

### BACKGROUND

1. Technical Field

The disclosure generally relates to processes for surface treating aluminum or aluminum alloy and articles made of aluminum or aluminum alloy treated by the process.

2. Description of Related Art

Aluminum and aluminum alloy are widely used in manufacturing components (such as housings) of electronic devices because of their many desirable properties such as light weight and quick heat dissipation. However, aluminum and aluminum alloy have a relatively low erosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for surface treating aluminum or aluminum alloy and articles made of aluminum or aluminum alloy treated by the process. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated by the present process.

FIG. 2 is a schematic view of a magnetron sputtering machine for processing an exemplary article shown in FIG. 1.

FIG. 3 is a field emission stereoscan photograph microscope (100,000× magnified) of a composite coating formed by an exemplary embodiment of the present process.

4 is a field emission stereoscan photograph microscope (50,000× magnified) of a chromium nitride coating deposited by magnetron sputtering.

### DETAILED DESCRIPTION

An exemplary process for surface treating aluminum or aluminum alloy may include the following steps.

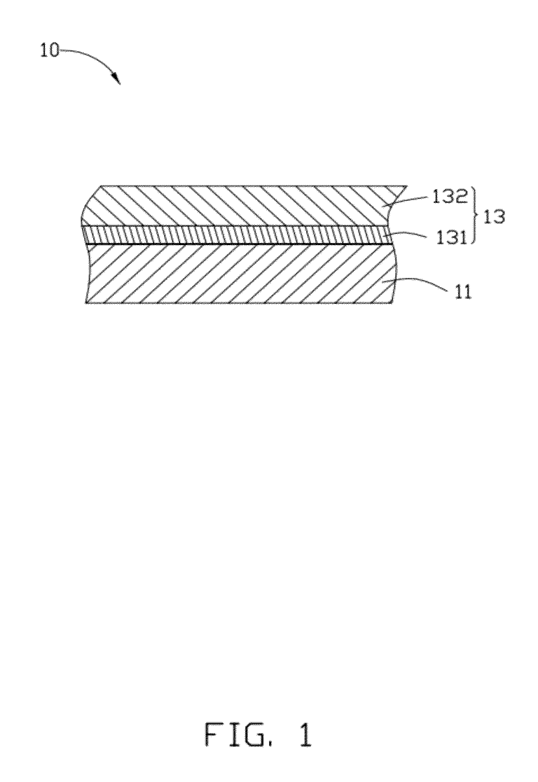

Referring to FIG. 1, a substrate 11 is provided. The substrate 11 is made of aluminum or aluminum alloy.

First, the substrate 11 is pretreated. For example, the substrate 11 is ultrasonically cleaned with a solution (e.g., alcohol or Acetone) in an ultrasonic cleaner, to remove impurities such as grease or dirt from the substrate 11. Then, the substrate is dried.

A composite coating 13 is formed on the substrate 11 by magnetron sputtering. The composite coating 13 includes a titanium oxynitride (TiON) coating 131 and a chromium oxynitride (CrON) coating 132. The magnetron sputtering for forming the composite coating 13 may be performed by the following steps.

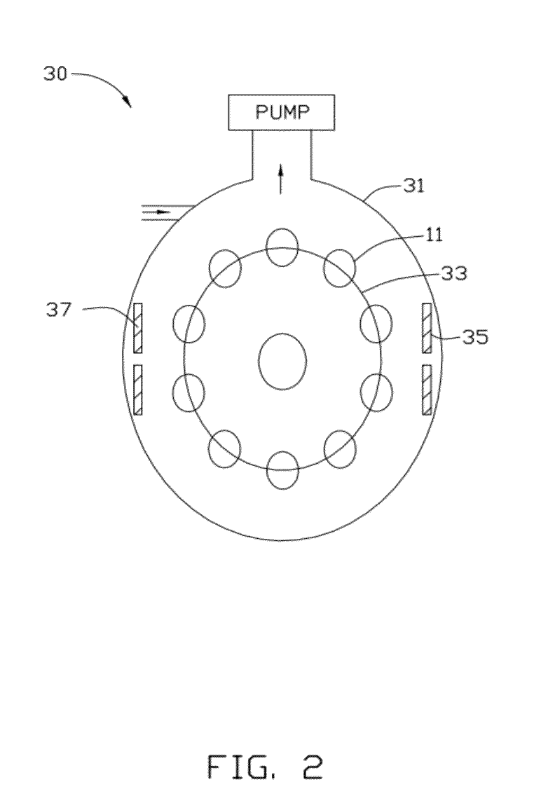

The TiON coating 131 is directly formed on the substrate 11 by magnetron sputtering. The substrate 11 is retained on a rotating bracket 33 in a vacuum chamber 31 of a magnetron sputtering machine 30 as shown in FIG. 2. The vacuum chamber 31 is evacuated to maintain an internal pressure of about 5×10⁻³ Pa-9×10⁻³ Pa and the inside of the chamber 31 is heated to a temperature of about 100° C.-180° C. The speed of the rotating bracket 33 is between about 0.5 revolutions per minute (rpm) and about 1 rpm. Argon, oxygen, and nitrogen are simultaneously supplied into the vacuum chamber 31, with the argon as a sputtering gas, and the oxygen and nitrogen as reactive gas. The flux of argon is in a range of about 150 standard cubic centimeters per minute (sccm) to about 300 sccm. The flux of oxygen is in a range of about 10 sccm-100 sccm, and the flux of nitrogen is in a range of about 10 sccm-80 sccm. A bias voltage is applied to the substrate 11 in a range of about −100 volts (V) to about −300 V. At least one titanium target 35 is evaporated at a power of about 6 kW-12 kW with the duty cycle of about 40%-60% for about 0.5 hour-1.5 hours, depositing the TiON coating 131 on the substrate 11. The power may be a medium-frequency AC power.

Subsequently, the CrON coating 132 is directly formed on the TiON coating 131 also by magnetron sputtering. This step may be carried out in the same magnetron sputtering machine 30. The vacuum chamber 31 is evacuated to maintain a pressure of about 5×10⁻³ Pa-9×10⁻³ Pa, and the inside of the chamber 31 is heated to a temperature of about 100° C.-180° C. The speed of the rotating bracket 33 is about 0.5 revolutions per minute (rpm)-1 rpm. Argon, oxygen, and nitrogen are simultaneously supplied into the vacuum chamber 31. The flux of argon is in a range of about 150 sccm-300 sccm. The flux of oxygen is in a range of about 10 sccm-150 sccm, and the flux of nitrogen is in a range of about 10 sccm-100 sccm. A bias voltage is applied to the substrate 11 in a range of about −100 V to about −300 V. At least one chromium target 37 is evaporated at a power between about 6 kW-12 kW with the duty cycle of about 40%-60% for about 0.5 hour-3 hours, depositing the CrON coating 132 on the TiON coating 131. The composite coating 13 including the TiON coating 131 and the CrON coating 132 has a thickness of about 0.6 μm-2.5 μm.

The total pressure created by the nitrogen and the oxygen during sputtering the CrON coating 132 may be larger than the total pressure created by the nitrogen and the oxygen during sputtering the TiON coating 131. The ratio of the nitrogen flux to the oxygen flux during the sputtering of both the TiON coating 131 and the CrON coating 132 may be about 1:1 to 1:3.

FIG. 1 shows a cross-section of an exemplary article 10 made of aluminum or aluminum alloy and processed by the surface treating as described above. The article may be housings for electronic devices, such as mobile phones. The article 10 includes the substrate 11 made of aluminum or aluminum alloy and the composite coating 13 formed on the substrate 11. The composite coating 13 includes the TiON coating 131 directly formed on the substrate 11 and the CrON coating 132 directly formed on the TiON coating 131. In the TiON coating 131, the atomic percentage of Ti is about 40%-65%; the atomic percentage of O is about 25%-50%; the atomic percentage of N is about 10%-20%. In the CrON coating 132, the atomic percentage of Cr is about 50%-70%; the atomic percentage of O is about 20%-45%; the atomic percentage of N is about 5%-10%. The composite coating 13 formed by this exemplary method comprises crystal grains having an average particle diameter of about 4 nm-7 nm. Crystal grains having an average particle diameter of about 4 nm-7 nm have smaller space between crystal grains than in material have lager average particle diameters. Thus, the composite coating 13 has improved in density and the article 10 coated with the composite coating 13 has an improved erosion resistance since it becomes harder for contaminants to enter the spaces between the crystal grains.

### EXAMPLES

Experimental examples of the present disclosure are described as followings.

### Example 1

A sample of aluminum alloy substrate was ultrasonically cleaned for about 30 minutes and then was placed into the vacuum chamber 31 of the magnetron sputtering machine 30. The vacuum chamber 31 was evacuated to a pressure of about 8×10⁻³ Pa and heated to about 120° C. The speed of the rotating bracket 33 was about 0.5 rpm. Argon, oxygen, and nitrogen were simultaneously floated into the vacuum chamber. The flux of the argon was about 150 sccm. The flux of oxygen was about 30 sccm, and the flux of the nitrogen was about 20 sccm. The bias voltage applied to the substrate was about −200 volts. Titanium targets were evaporated at about 8 kW with the duty cycle of about 50% for about 0.5 hour, depositing a TiON coating on the substrate. Then the titanium targets were switched off. The oxygen flux was adjusted to 40 sccm. The nitrogen flux was adjusted to 30 sccm. Chromium targets were evaporated at about 8 kw with the duty cycle of about 50% for about 1 hour, depositing a CrON coating on the TiON coating with the remaining parameters were unchanged.

### Example 2

Unlike example 1, in example 2, the oxygen flux was about 80 sccm, and the nitrogen flux was about 50 sccm during sputtering of the CrON coating. Except for the above differences, the remaining conditions of example 2 were the same as example 1. An article of aluminum alloy coated with a composite coating including a TiON coating and a CrON coating was obtained according to example 2.

The samples processed in example 1 and 2 have similar microcosmic configurations and surface topographies, therefore have similar erosion resistance.

### Comparison Example

A sample of aluminum alloy substrate was processed by magnetron sputtering using the magnetron sputtering machine 30. Unlike the example 1, the target material was chromium and the reactive gas was nitrogen in the comparison example. The flux of the nitrogen was about 60 sccm. Except the above difference, the remaining conditions of the comparison example were the same as example 1. A chromium nitride (CrN) coating was deposited on the aluminum alloy substrate.

### Results of the Above Examples

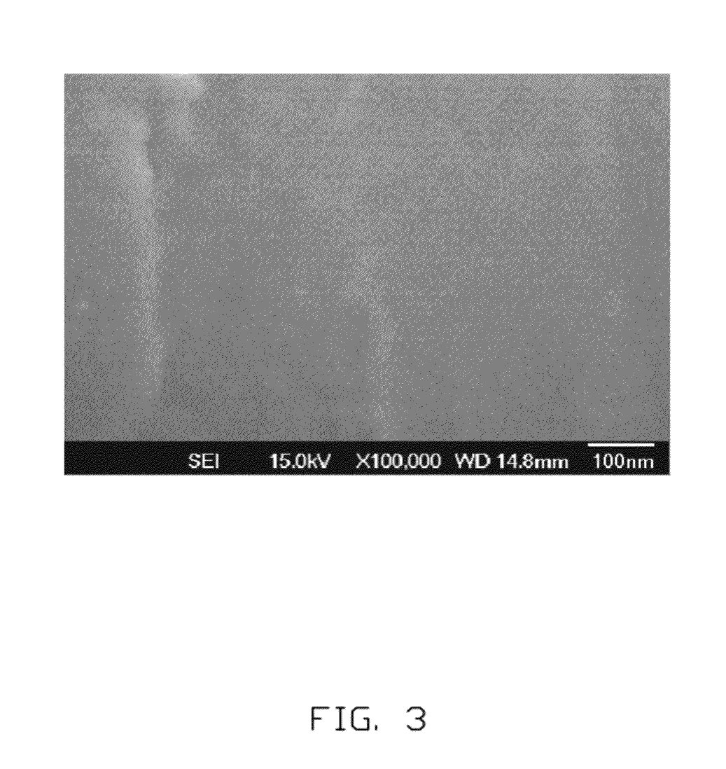

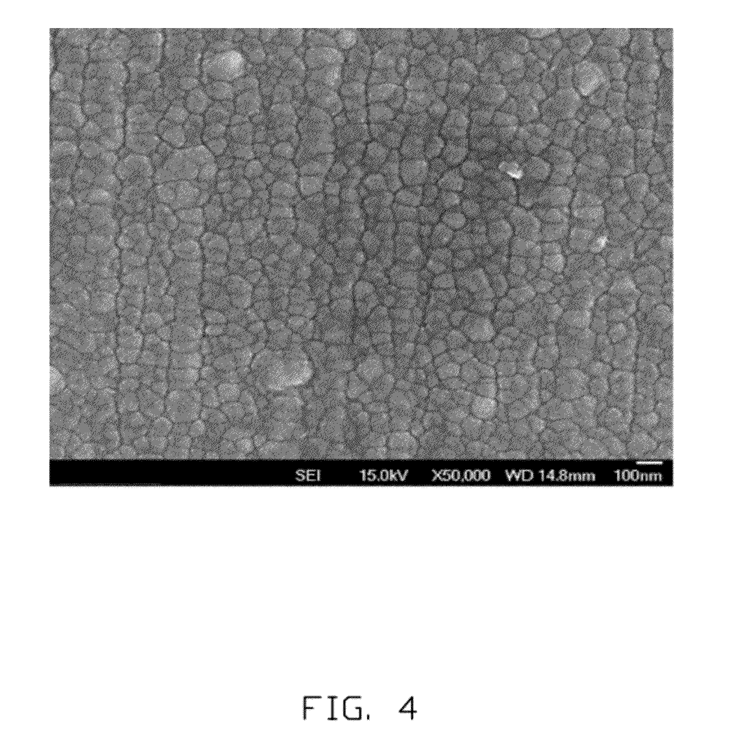

Referring to FIGS. 3 and 4, the composite coating formed in example land the CrN coating formed in the comparison example were observed by scanning electronic microscopy (SEM). A “JSM-6701F” type field emission scanning electronic microscope sold by JEOL Ltd is used. The scanning indicated that the composite coating comprised small-sized crystal grains with very small spaces among the crystal grains. In contrast, the CrN coating comprised large-sized crystal grains. Furthermore, the CrN coating had a large number of big spaces among the crystal grains. Thus, the composite coating has a higher density than the CrN coating.

Additionally, an neutral salt spray test was implemented to the samples coated with the composite coatings and the sample coated with CrN coating. The test conditions included 5% NaCl (similar to salt-fog chloride levels), that was neutral at 35° C. to simulate condensing gases with moisture and salt. The test was an accelerated corrosion test for assessing coating performance Obvious erosion was observed with the sample coated with CrN coating after about 4 hours. However, after about 72 hours, erosion began to be observed the samples coated with the composite coatings.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for surface treating aluminum or aluminum alloy, the method comprising the following steps of:
providing a substrate made of aluminum or aluminum alloy;
forming a TiON coating on the substrate by magnetron sputtering, using aluminum as a target, and nitrogen and oxygen as reactive gases; and
forming a CrON coating on the TiON coating by magnetron sputtering, using chromium as a target, and nitrogen and oxygen as reactive gases.

2. The method as claimed in claim 1, wherein the ratio of the nitrogen flux to the oxygen flux during the sputtering of both the TiON coating and the CrON coating is about 1:1 to 1:3.

3. The method as claimed in claim 2, wherein during magnetron sputtering of the TiON coating, the oxygen flux is about 10 sccm-100 sccm, the nitrogen flux is about 10 sccm-80 sccm.

4. The method as claimed in claim 3, wherein during magnetron sputtering the TiON layer, the substrate is retained in a vacuum chamber of a magnetron sputtering machine; the vacuum chamber is evacuated to a pressure of about 5×10⁻³ Pa-9×10⁻³ Pa, and is heated to a temperature of about 100° C.-180° C.; argon, the oxygen, and the nitrogen are simultaneously supplied into the vacuum chamber, the flux of the argon is about 150 sccm-300 sccm; a bias voltage is applied to the substrate in a range from about −100V to about −300V; the titanium target is evaporated at a power of about 6 kW-12 kW for about 0.5 hours-1.5 hours.

5. The method as claimed in claim 2, wherein during magnetron sputtering CrON coating, the flux of the oxygen is about 10 sccm-150 sccm, the flux of the nitrogen is about 10 sccm-100 sccm.

6. The method as claimed in claim 5, wherein during magnetron sputtering the CrON layer, the substrate is retained in a vacuum chamber of a magnetron sputtering machine; the vacuum chamber is evacuated to maintain a pressure of about 5×10⁻³ Pa-9×10⁻³ Pa, and is heated to maintain a temperature of about 100° C.-180° C.; argon, the oxygen, and the nitrogen are simultaneously supplied into the vacuum chamber, the flux of the argon is about 150 sccm-300 sccm; a bias voltage is applied to the substrate in a range from about −100V to about −300V; the chromium target is evaporated at a power of about 6 kW-12 kW for about 0.5 hours-3 hours.

7. The method as claimed in claim 1, wherein the TiON coating comprises about 40%-65% of atomic Ti, about 25%-50% of atomic O, and about 10%-20% of atomic N.

8. The method as claimed in claim 1, wherein the CrON coating comprises about 50%-70% of atomic Cr, about 20%-45% of atomic O, and about 5%-10% of atomic N.

9. The method as claimed in claim 1, wherein the composite coating comprises crystal grains having an average particle diameter of about 4 nm-7 nm.

10. An article, comprising:
a substrate made of aluminum or aluminum alloy; and
a composite formed on the substrate, the composite comprising:
a TiON coating formed on the substrate; and
a CrON coating formed on the TiON coating.

11. The article as claimed in claim 10, wherein in TiON coating comprises about 40%-65% of atomic Ti; about 25%-50% of atomic O; and about 10%-20% of atomic N.

12. The article as claimed in claim 10, wherein in the CrON coating comprises about 50%-70% of atomic Cr; about 20%-45% of atomic O; and about 5%-10% of atomic N.

13. The article as claimed in claim 10, wherein the composite coating comprises crystal grains having an average particle diameter of about 4 nm-7 nm.

14. The article as claimed in claim 10, wherein the composite coating has a thickness of about 0.6 μm-2.5 μm.

15. The article as claimed in claim 10, wherein the composite coating is formed by magnetron sputtering.

16. The article as claimed in claim 10, wherein the article is a housing of electronic devices.
